(19) United States
(12) Patent Application Publication
(10) Pub. No.: US 2008/0231376 A1
(43) Pub. Date: Sep. 25, 2008

(54) Oscillation circuit controlling phase difference of output signals

(75) Inventors: Masaki Kinoshita, Ota-shi (JP); Satoshi Terada, Gunma-ken (JP); Takashi Kamimura, Ebina-shi (JP)

Correspondence Address: OSHA LIANG L.L.P., 1221 MCKINNEY STREET, SUITE 2800, HOUSTON, TX, 77010, US

(73) Assignee: Sanyo Electric Co., Ltd., Osaka (JP)

(21) Appl. No.: 11/724,015

(22) Filed: Mar. 14, 2007

(51) Int. Cl. H03L 7/00

(52) U.S. Cl. 331/34

(57) ABSTRACT

A ring oscillation circuit composed of multiple op amps connected in series in a loop configuration is included to output a first output signal by adding multiple output signals of multiple op amps and to output a second output signal by adding all remaining output signals of multiple op amps.

### CROSS-REFERENCE TO RELATED APPLICATIONS

The entire disclosure of Japanese Patent Application No. 2005-351390 including specifications, claims, drawings, and abstracts is incorporated herein by references.

### BACKGROUND OF THE INVENTION

1. Field of the Invention

The present invention relates to a ring oscillation circuit from which output signals having an accurate phase difference can be obtained.

2. Description of the Related Art

In a radio communication system, a receiver uses a local signal that is generated at a local oscillator to down convert a received signal at a radio frequency to a local intermediate frequency f_{IF}. For example, when receiving a radio signal A at a frequency f_{A}, the local oscillator generates a local signal at a frequency f_{LO} satisfying f_{A}−f_{LO}=f_{IF}. At this time, a radio signal B at a frequency f_{B} satisfying f_{LO}−f_{B}=f_{IF} is also converted to the intermediate frequency f_{IF}. Therefore, if the radio signal B at frequency f_{B} exists, the radio frequency B is superimposed onto the desired radio frequency A and received. The reception of the radio signal B is commonly referred to as image reception.

Conventionally, a mixer for reducing noise due to image reception or demodulating an I/Q composite signal that has undergone orthogonal transformation requires a circuit for generating local signals having a mutual phase difference of 90°. A ring oscillation circuit is an example of a known circuit for generating signals having this type of phase difference.

As shown in FIG. 4, a ring oscillation circuit 100 connects multiple op amps 10 in series. FIG. 4 shows an example where four op amps 10-1 to 10-4 are connected in series. The interconnected op amps 10 are connected so that the phase of the differential output signal of the previous stage and the differential output signal of the next stage is inverted at one point and not inverted at the remaining points. Namely, the non-inverted output terminal of the op amp 10-1 of the first stage is connected to the non-inverted input terminal of the op amp 10-2 of the second stage and the inverted output terminal of the op amp 10-1 of the first stage is connected to the inverted input terminal of the op amp 10-2 of the second stage. Similarly, the non-inverted output terminals of the op amps 10-2, 10-3 from the second stage are connected to the non-inverted input terminals of the op amps 10-3, 10-4 of the next stage and the inverted output terminals of the op amps 10-2, 10-3 are connected to the inverted input terminals of the op amps 10-3, 10-4 of the next stage. The inverted output terminal of the op amp 10-4 of the final stage is connected to the non-inverted input terminal of the op amp 10-1 of the first stage and the non-inverted output terminal of the op amp 10-4 of the final stage is connected to the inverted input terminal of the op amp 10-1 of the first stage.

By connecting multiple op amps 10-1 to 10-4 into a ring configuration in this manner, the signal that is input by the non-inverted input terminal of the op amp 10-1 of the first stage and the signal that is output from the inverted output terminal of the op amp 10-4 of the final stage are in phase, the signal that is input by the inverted input terminal of the op amp 10-1 of the first stage and the signal that is output from the non-inverted output terminal of the op amp 10-4 of the final stage are in phase, and the phase difference of the overall ring oscillation circuit 100 is 360°. Therefore, ideally, as shown in FIG. 4, the signals that are input by the non-inverted input terminals from the second stage to the final stage have phase differences of 45°, 90°, and 135° with respect to the signal that is input by the non-inverted input terminal of the op amp 10-1 of the first stage and the signals that are input by the inverted input terminals from the first stage to the final stage have phase differences of 180°, 225°, 270°, and 315°. In this manner, the ring oscillation circuit 100 is used so that ideally signals having desired phase differences can be obtained.

When actually using the ring oscillation circuit 100, as shown in FIG. 5, it is necessary to obtain signals via a buffer device 12 by providing lines to obtain the output signals from the lines interconnecting the op amps 10-1 to 10-4. When a circuit is configured in this manner, the phase differences of the output signals of the op amps 10-1 to 10-4 in the ring oscillation circuit 100 deviate from the above-mentioned ideal values due to the influence of wiring resistance, parasitic capacitance, input impedance of the buffer device 12, and so forth, so that a problem arises where the original purpose of obtaining signals that have accurate phase differences cannot be achieved.

### SUMMARY OF THE INVENTION

An aspect of the present invention is an oscillation circuit that includes a ring oscillation circuit composed by connecting multiple op amps in series in a loop configuration and includes a first addition circuit for adding a plurality of output signals output by a plurality of op amps and outputting a first output signal and a second addition circuit for adding all signals output by said plurality of op amps other than the plurality of signals added in the first addition circuit and outputting a second output signal.

### BRIEF DESCRIPTION OF THE DRAWINGS

Preferred embodiments of the present invention will be described in detail based on the following drawings, wherein:

FIG. 1 shows an overall configuration of an oscillation circuit in an embodiment of the present invention;

FIG. 2 shows a configuration of a ring oscillation circuit in the embodiment of the present invention;

FIG. 3 is a vector diagram illustrating an action of the ring oscillation circuit in the embodiment of the present invention;

FIG. 4 shows a basic configuration of the ring oscillation circuit in the related art; and

FIG. 5 shows a configuration of the ring oscillation circuit in the related art.

### DESCRIPTION OF THE PREFERRED EMBODIMENTS

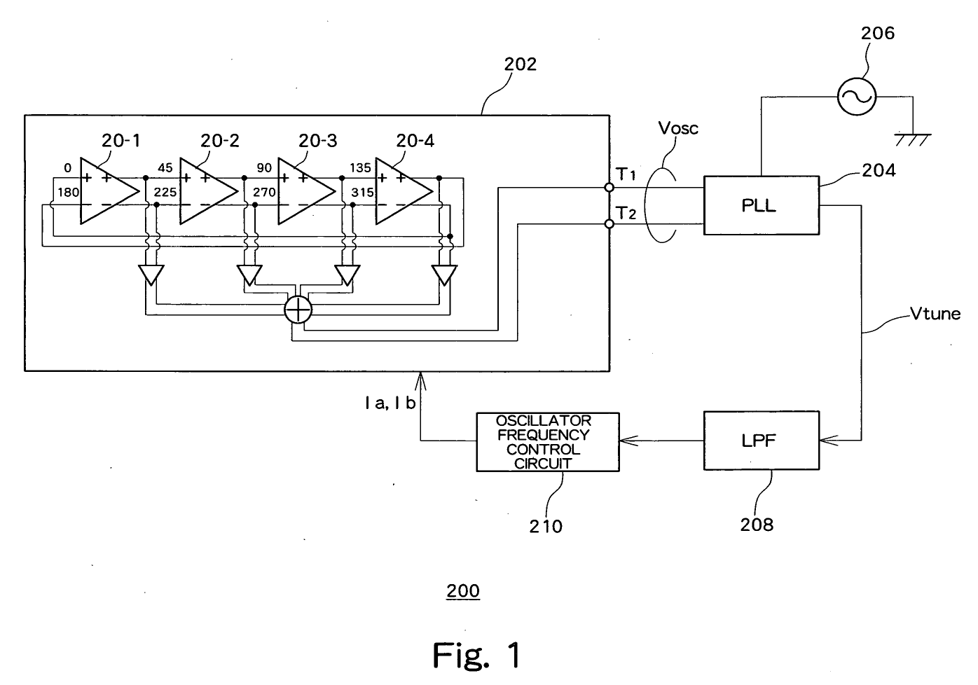

As shown in FIG. 1, an oscillation circuit 200 in an embodiment of the present invention is composed to include a ring oscillation circuit 202, a phase-locked loop (PLL) 204, a reference signal source 206, a low-pass filter (LPF) 208, and an oscillation frequency control circuit 210. The oscillation circuit 200 outputs, respectively from output terminals T1 and T2, output signals Vout1 and Vout2 having a mutual phase difference of 180° at a frequency f. The output signals Vout1 and Vout2 are used as a reference oscillation signal V_{osc} for the PLL 204.

The ring oscillation circuit 202 is composed to include multiple differential op amps 20 capable of variably controlling the transfer time of signals from input to output in response to current that is output by the oscillation frequency control circuit 210. The multiple op amps 20 are interconnected in series to compose a main section of the ring oscillation circuit 202. Furthermore, the ring oscillation circuit 202 generates and outputs the output signals Vout1 and Vout2. The configuration of the ring oscillation circuit 202 will be detailed hereinafter.

The PLL 204 generates and outputs an oscillation frequency control voltage Vₜᵤₙₑ in accordance with a phase difference between the oscillation signal V_{osc} that is output by the ring oscillation circuit 202 and the reference signal that is output by the reference signal source 206. The oscillation frequency control voltage Vₜᵤₙₑ is smoothed by the LPF 208 having a predetermined filter coefficient and input by the oscillation frequency control circuit 210.

The oscillation frequency control circuit 210 is configured to include a differential amplifier. The oscillation frequency control circuit 210 receives the smoothed oscillation frequency control voltage Vₜᵤₙₑ and varies the ratio of two output currents Ia and Ib in accordance with the difference between the oscillation frequency control voltage Vₜᵤₙₑ and a predetermined reference voltage Vc. For example, the ratio of the values of the output currents Ia and Ib is adjusted so that when the oscillation frequency control voltage Vₜᵤₙₑ decreases, the output current ratio Ia/Ib is increased, and when the oscillation frequency control voltage Vₜᵤₙₑ increases, the output current ratio Ia/Ib is decreased. The output currents Ia and Ib are respectively supplied to the op amps 20 that are included in the ring oscillation circuit 202 and utilized to control the oscillation frequency.

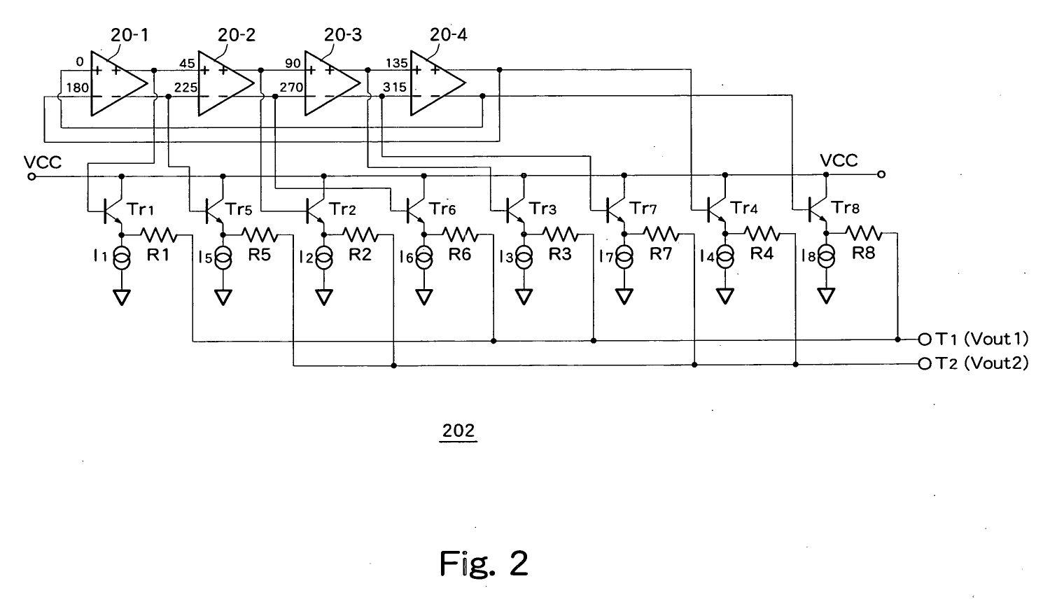

FIG. 2 shows a specific configuration of the ring oscillation circuit 202. The ring oscillation circuit 202 is composed to include op amps 20-1 to 20-4, transistors Tr1 to Tr8, resistors R1 to R8, and current supplies I1 to I8.

The main portion of the ring oscillation circuit 202 in the present embodiment includes four op amps 20-1 to 20-4 and has a similar configuration to that of the above-mentioned ring oscillation circuit 100. Namely, the four op amps 20-1 to 20-4 are connected in series so that the phase of a differential output of one stage and the differential output of the next stage is inverted at one point and not inverted at the remaining points. More specifically, the non-inverted output terminal of the op amp 20-1 of the first stage is connected to the non-inverted input terminal of the op amp 20-2 of the second stage and the inverted output terminal of the op amp 20-1 of the first stage is connected to the inverted input terminal of the op amp 20-2 of the second stage. Similarly, the non-inverted output terminals of the op amps 20-2, 20-3 from the second stage are connected to the non-inverted input terminals of the op amps 20-3, 20-4 of the next stages and the inverted output terminals for the op amps 20-2, 20-3 are connected to the inverted input terminals of the op amps 20-3, 20-4 of the next stages. The inverted output terminal of the op amp 20-4 of the final stage is connected to the non-inverted input terminal of the op amp 20-1 of the first stage and the non-inverted output terminal of the op amp 20-4 of the final stage is connected to the inverted input terminal of the op amp 20-1 of the first stage.

In each of the op amps 20-1 to 20-4, a high-speed path and a low-speed path are provided in parallel between the input terminal and output terminal. The output current Ia of the oscillation frequency control circuit 210 is the current supply for the differential amplifier circuits of the high-speed paths in op amps 20-1 to 20-4. On the other hand, the output current Ib of the oscillation frequency control circuit 210 is the current supply for the differential amplifier circuit of the low-speed paths in op amps 20-1 to 20-4. When the oscillation frequency control voltage Vₜᵤₙₑ decreases and the output current Ia increases, the signal transfers at the high-speed paths of the op amps 20-1 to 20-4 dominate so that the overall signal transfer time decreases for the op amps 20-1 to 20-4 and the phase delay of the oscillation signal V_{osc} can be reduced. On the other hand, when the oscillation frequency control voltage Vₜᵤₙₑ increases and the output current Ib increases, the signal transfers at the low-speed paths of the op amps 20-1 to 20-4 dominate so that the overall signal transfer time increases for the op amps 20-1 to 20-4 and the phase advance of the oscillation signal V_{osc} can be reduced.

Furthermore, the output terminals of the op amps 20-1 to 20-4 are connected to an emitter-follower circuit. The emitter-follower circuit forms two addition circuits. The non-inverted output terminal of the op amp 20-1 is connected to the base of the transistor Tr1, the non-inverted output terminal of the op amp 20-2 is connected to the base of the transistor Tr2, the non-inverted output terminal of the op amp 20-3 is connected to the base of the transistor Tr3, and the non-inverted output terminal of the op amp 20-4 is connected to the base of the transistor Tr4. Furthermore, the inverted output terminal of the op amp 20-1 is connected to the base of the transistor Tr5, the inverted output terminal of the op amp 20-2 is connected to the base of the transistor Tr6, the inverted output terminal of the op amp 20-3 is connected to the base of the transistor Tr7, and the inverted output terminal of the op amp 20-4 is connected to the base of the transistor Tr8. A supply voltage Vcc is applied to the collectors of the transistors Tr1 to Tr8 and the emitters of the transistors Tr1 to Tr8 are grounded via the current supplies I1 to I8.

Furthermore, the emitter of the transistor Tr1, the emitter of the transistor Tr3, the emitter of the transistor Tr6, and the emitter of the transistor Tr8 are connected to the output terminal T1 respectively via the resistors R1, R3, R6, and R8. The emitter of the transistor Tr2, the emitter of the transistor Tr4, the emitter of the transistor Tr5, and the emitter of the transistor Tr7 are connected to the output terminal T2 respectively via the resistors R2, R4, R5, and R7. In this manner, the signals that are output from the op amps 20-1 to 20-4 via the emitter-follower circuits are added and output.

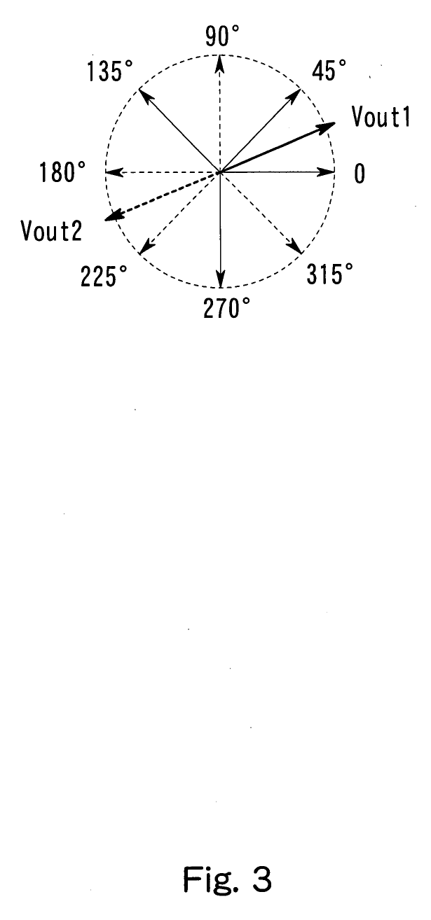

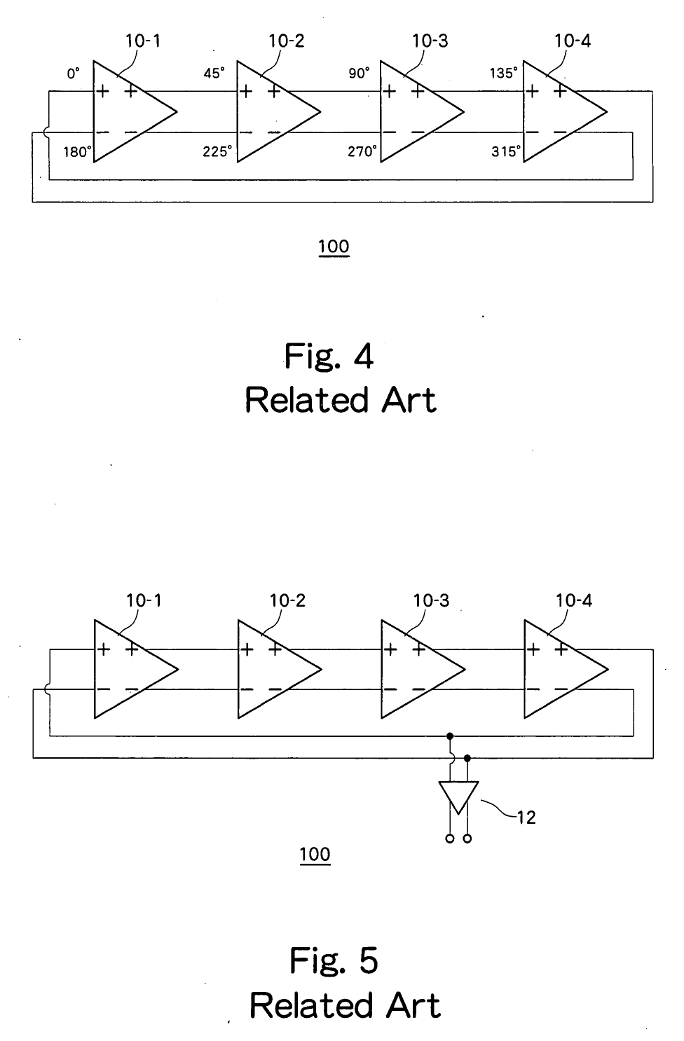

Signals having phases respectively shifted by 45°, 90°, 135°, and 180° with respect to the signal that is input by the non-inverted input terminal of the op amp 20-1 are output from the non-inverted output terminals of the op amps 20-1 to 20-4. Furthermore, signals having phases respectively shifted by 225°, 270°, 315°, and 360° (identical phase to that of the signal that is input by the non-inverted input terminal of the op amp 20-1) with respect to the signal that is input by the non-inverted input terminal of the op amp 20-1 are output from the inverted output terminals of the op amps 20-1 to 20-4. Namely, as shown in FIG. 3, signals having phases shifted by 0° (in phase), 45°, 135°, and 270° with respect to the signal that is input by the non-inverted input terminal of the op amp 20-1 are added and output as the output voltage Vout1 from the output terminal T1 and signals having phases shifted by 90°, 180°, 225°, and 315° with respect to the signal that is input by the non-inverted input terminal of the op amp 20-1 are added and output as the output voltage Vout2.

By adding and outputting signals having phases respectively shifted in this manner, as shown in FIG. 3, the output voltage Vout1 and the output voltage Vout2 have phases mutually shifted by 180°. Therefore, the output voltage Vout1 and the output voltage Vout2 can be used as input signals for the PLL 204.

Because all of the signals from the output terminals of all the op amps forming the oscillation circuit 200 are obtained, added, and output at the ring oscillation circuit 202, deviations from the ideal phase difference values of the output signals due to the influence of impedance from parasitic capacitance or wiring resistance can be minimized. Therefore, a local signal having an accurate phase difference can be obtained. It should be noted that the PLL circuit has a high input impedance so that the influence on the ring oscillation circuit 202 is small.

Although an example circuit configuration generating signals having a mutual phase difference of 180° was used to illustrate the present embodiment, the embodiment is not limited to such a configuration. By changing the combination of signals that are input to the respective addition circuits from signals having phase differences of 45°, 90°, 135°, 180°, 225°, 270°, 315°, and 360°, it is possible to obtain signals having a mutual phase difference of 90°. As a result, a mixer can be configured to reduce noise due to image reception and to demodulate an I/Q composite signal that has undergone orthogonal transformation.

Furthermore, although the example ring oscillation circuit in the embodiment is configured from four op amps, the number of op amps may be greater than four. Specifically, any configuration that outputs from all output terminals of all op amps forming a ring oscillation circuit and combines and outputs the output signals to yield desired phase differences falls within the scope of the technical idea of the present invention. However, configuring the ring oscillation circuit with four op amps simplifies the circuit configuration and makes it possible to stabilize the oscillation action as well as constrain manufacturing costs.

While there has been described what are at present considered to be preferred embodiments of the invention, it will be understood that various modifications may be made thereto, and it is intended that the appended claims cover all such modifications as fall within the true spirit and scope of the invention.

What is claimed is:

1. An oscillation circuit comprising:
a first addition circuit for adding a plurality of output signals output by a plurality of op amps and outputting a first output signal;
a second addition circuit for adding all signals output by said plurality of op amps other than the plurality of signals added in the first addition circuit and outputting a second output signal;
said plurality of op amps are connected in series in a loop configuration to form a ring oscillation circuit.

2. An oscillation circuit according to claim 1, wherein:
said ring oscillation circuit comprises a first op amp to a fourth op amp as said plurality of op amps;
a non-inverted output terminal of said first op amp is connected to a non-inverted input terminal of said second op amp, a non-inverted output terminal of said second op amp is connected to a non-inverted input terminal of said third op amp, a non-inverted output terminal of said third op amp is connected to a non-inverted input terminal of said fourth op amp, a non-inverted output terminal of said fourth op amp is connected to an inverted input terminal of said first op amp, an inverted output terminal of said first op amp is connected to an inverted input terminal of said second op amp, an inverted output terminal of said second op amp is connected to an inverted input terminal of said third op amp, an inverted output terminal of said third op amp is connected to an inverted input terminal of said fourth op amp, an inverted output terminal of said fourth op amp is connected to a non-inverted input terminal of said first op amp;
said first addition circuit adds output signals from the non-inverted output terminal of said first op amp, the non-inverted output terminal of said third op amp, the inverted output terminal of said second op amp, and the inverted output terminal of said fourth op amp as said first output signal;
said second addition circuit adds output signals from the non-inverted output terminal of said second op amp, the non-inverted output terminal of said fourth op amp, the inverted output terminal said first op amp, and the inverted output terminal of said third op amp as said second output signal.

3. An oscillation circuit according to claim 1, wherein each of said plurality of op amps comprises a high-speed path and a low-speed path mutually disposed in parallel between the input terminal and output terminal.

4. An oscillation circuit according to claim 2, wherein each of said plurality of op amps comprises a high-speed path and a low-speed path mutually disposed in parallel between the input terminal and output terminal.

5. An oscillation circuit according to claim 1 further comprising:
a phase-locked loop circuit for receiving an oscillation signal that is output from said ring oscillation circuit and outputting an oscillation frequency control signal in accordance with a phase shift with a reference signal that is output by a reference signal source; and
an oscillation frequency control circuit for controlling the oscillation frequency of said ring oscillation circuit on the basis of said oscillation frequency control signal.

6. An oscillation circuit according to claim 2, comprising:
a phase-locked loop circuit for receiving an oscillation signal that is output by said ring oscillation circuit and outputting an oscillation frequency control signal in accordance with a phase difference with a reference signal that is output by a reference signal source; and
an oscillation frequency control circuit for controlling the oscillation frequency of said ring oscillation circuit on the basis of said oscillation frequency control signal.

7. An oscillation circuit according to claim 3, comprising:
a phase-locked loop circuit for receiving an oscillation signal that is output by said ring oscillation circuit and outputting an oscillation frequency control signal in accordance with a phase difference with a reference signal that is output by a reference signal source; and
an oscillation frequency control circuit for controlling the oscillation frequency of said ring oscillation circuit by controlling the high-speed path and low-speed path of each of said plurality of op amps on the basis of said oscillation frequency control signal.
